(19) United States
(12) Patent Application Publication
(10) Pub. No.: US 2025/0105493 A1
(43) Pub. Date: Mar. 27, 2025

(54) ELECTRONIC DEVICE INCLUDING ANTENNA MODULE

(71) Applicant: Samsung Electronics Co., Ltd., Suwon-si (KR)

(72) Inventors: Hyunyoung ROH, Suwon-si (KR); Jeong PARK, Suwon-si (KR)

(21) Appl. No.: 18/896,063

(22) Filed: Sep. 25, 2024

Related U.S. Application Data
(63) Continuation of application No. PCT/KR2024/013920, filed on Sep. 12, 2024.

(30) Foreign Application Priority Data
Sep. 25, 2023 (KR) 10-2023-0128288
Nov. 22, 2023 (KR) 10-2023-0163584

(51) Int. Cl. H01Q 1/24; H01Q 9/04; H01Q 9/16

(52) U.S. Cl. CPC H01Q 1/243; H01Q 9/0407; H01Q 9/16

(57) ABSTRACT

The disclosure relates to an electronic device. An electronic device according to an embodiment of the disclosure may include: a housing including a side wall, wherein the side wall includes a recess recessed from an outer surface of the side wall; a non-conductive cap disposed in the recess and including a protruding portion passing through the recess; an antenna module disposed opposite to the cap with respect to the recess and including at least one antenna element disposed to face the recess; and a bracket disposed inside the housing such that the antenna module is mounted thereon and including a coupling hole through which the protruding portion is inserted.

### CROSS-REFERENCE TO RELATED APPLICATIONS

This application is a continuation of International Application No. PCT/KR2024/013920 designating the United States, filed on Sep. 12, 2024, in the Korean Intellectual Property Receiving Office and claiming priority to Korean Patent Application Nos. 10-2023-0128288, filed on Sep. 25, 2023, and 10-2023-0163584, filed on Nov. 22, 2023, in the Korean Intellectual Property Office, the disclosures of each of which are incorporated by reference herein in their entireties.

### BACKGROUND

### Field

The disclosure relates to an electronic device, for example, an electronic device including an antenna module.

### Description of Related Art

Remarkable developments in information and communication technology and semiconductor technology have brought about a rapid increase in distribution and use of various electronic devices. In particular, recent electronic devices are being developed so as to be carried and used for communication.

Electronic devices may refer, for example, to devices that perform specific functions according to installed programs, such as home appliances, electronic notebooks, portable multimedia players, mobile communication terminals, tablet PCs, video/audio devices, desktop/laptop computers, and vehicle navigation devices. For example, these electronic devices may output stored information as sound or video.

As the degree of integration of electronic devices increases and high-speed and high-capacity wireless communication becomes more common, various functions may be provided in a single electronic device such as a mobile communication terminal nowadays. For example, in addition to communication functions, entertainment functions such as games, multimedia functions such as music/video playback, communication and security functions such as mobile banking, and schedule management and electronic wallet functions are being integrated into a single electronic device. These electronic devices are being miniaturized so that users may conveniently carry them.

### SUMMARY

An electronic device according to an example embodiment of the disclosure may include: a housing including a side wall including a recess recessed from an outer surface of the side wall; a non-conductive cap disposed in the recess and including a protruding portion passing through the recess; an antenna module disposed opposite to the cap with respect to the recess and including at least one antenna element disposed to face the recess; and a bracket disposed inside the housing wherein the antenna module is mounted on the bracket and the bracket further including a coupling hole through which the protruding portion is inserted. An electronic device may restrict the bracket from moving inside the electronic device.

An electronic device according to an example embodiment of the disclosure may include: a housing including a side wall including a recess recessed from an outer surface of the side wall; a non-conductive cap disposed in the recess and including a protruding portion passing through the recess; an antenna module disposed opposite to the cap with respect to the recess and including at least one antenna element disposed to face the recess; and a bracket disposed inside the housing wherein the antenna module is mounted on the bracket and overlapping the end of the protruding portion. An embodiment may restrict the bracket from moving inside the electronic device.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a front perspective view illustrating an example electronic device according to various embodiments;

FIG. 3 is an exploded perspective view illustrating the rear of an electronic device according to various embodiments;

FIG. 4 is an exploded perspective view illustrating an example antenna assembly according to various embodiments;

FIG. 5 is an exploded perspective view of an example antenna assembly and a cap according to various embodiments;

FIG. 6 is a perspective view of a cap according to various embodiments;

FIG. 7 is a diagram illustrating a rear view of a portion of an electronic device according various embodiments;

FIG. 8 is a cross-sectional view taken along line A-A′ in FIG. 7 according to various embodiments;

FIG. 9 is a cross-sectional view taken along line B-B′ in FIG. 7 according to various embodiments;

FIG. 10 is a perspective view of a cap according to various embodiments;

FIG. 11 is a diagram illustrating a rear view of a portion of an electronic device according to various embodiments;

FIG. 12 is a perspective view of an example antenna assembly according to various embodiments;

FIG. 13A is a diagram illustrating a rear view of a portion of an electronic device according to various embodiments;

FIG. 13B is a cross-sectional view taken along line C-C′ in FIG. 13A according to various embodiments;

FIG. 14 is a diagram illustrating a front view of a bracket according to various embodiments;

FIG. 15A is a diagram illustrating a rear view of a portion of an electronic device according to various embodiments;

FIG. 15B is a cross-sectional view taken along line D-D′ in FIG. 15A according to various embodiments;

FIG. 16 is a diagram illustrating a rear view of a cap according to various embodiments;

FIG. 17 is an exploded perspective view of an antenna assembly and a cap according to various embodiments;

FIG. 18 is an enlarged view of a portion of the side wall shown in FIG. 17 with an antenna assembly disposed on the side wall according to various embodiments;

FIG. 19 is a diagram illustrating a rear view of a portion of an electronic device according to various embodiments; and

FIG. 20 is a cross-sectional view taken along line E-E′ in FIG. 19 according to various embodiments.

### DETAILED DESCRIPTION

The following description made with reference to the accompanying drawings may provide an understanding of various example implementations of the disclosure including the claims and equivalents thereof. Various example embodiments set forth in the following description includes various particular details to help the understanding. Therefore, it will be apparent to those skilled in the art that various changes and modifications may be made to various implementations described herein without departing from the scope and technical idea of the disclosure. In addition, descriptions of well-known functions and configurations may be omitted for clarity and brevity.

The terms and words used in the following description and claims are not limited to bibliographical meanings, but may be used to clearly and consistently describe the various embodiments set forth herein. Therefore, it will be apparent to those skilled in the art that the following description of various implementations of the disclosure is provided only for the purpose of explanation, rather than for the purpose of limiting the disclosure defined as the scope of protection and equivalents thereto.

It should be appreciated that a singular form such as “a,” “an,” or “the” also includes the meaning as a plural form, unless the context clearly indicates otherwise. Therefore, for example, “a component surface” may refer to one or more of component surfaces.

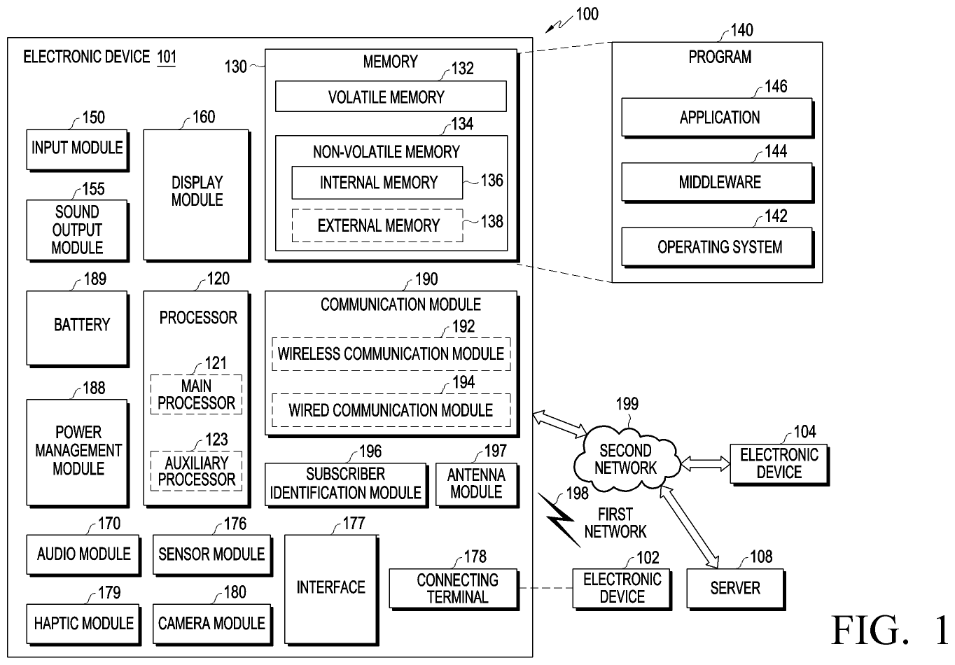

FIG. 1 is a block diagram illustrating an example electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the clement may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

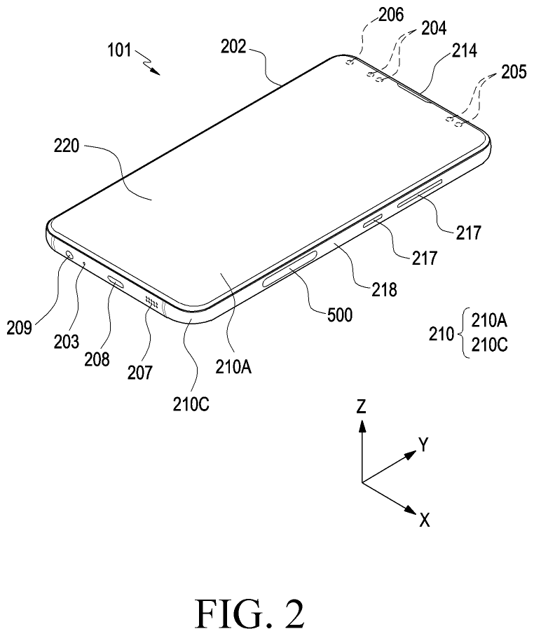

FIG. 2 is a front perspective view illustrating an example electronic device 101 according to various embodiments. Referring to FIG. 2, an electronic device 101 (e.g., the electronic device 101 in FIG. 1) according to an embodiment may include a housing 210 including a first surface (or front surface) 210A, a second surface (or rear surface), and a lateral surface 210C surrounding the space between the first surface 210A and the second surface. According to an embodiment, the first surface 210A may be formed, at least in part, by a front plate 202 (e.g., a glass plate or a polymer plate including various coating layers) having at least a portion that is substantially transparent. The lateral surface 210C may be coupled to the front plate 202 and may be formed by a lateral structure (or “lateral bezel structure”) 218 including metal and/or polymer.

According to an embodiment, the electronic device 101 may include at least one of a display 220, audio modules 203, 207, and 214, a sensor module 204, a camera module 205, a key input device 217, and a light-emitting element 206, and connector holes 208 and 209. In an embodiment, the electronic device 101 may exclude at least one (e.g., the key input device 217 or the light-emitting device 206) of the elements or may further include other elements.

The display 220 may be visible, for example, through the most area of the front plate 202. In an embodiment, at least a portion of the display 220 may be visible through the front plate 202 of the first surface 210A or through a portion of the lateral surface 210C. In an embodiment, the edges of the display 220 may be formed to be substantially the same as the outer shape of the front plate 202 adjacent thereto. In an embodiment (not shown), in order to expand the area to which the display 220 is visible, the distance between the outer edge of the display 220 and the outer edge of the front plate 202 may be formed to be substantially the same.

In an embodiment (not shown), a recess or opening may be formed in a portion of a screen display region of the display 220, and at least one or more of an audio module 214, a sensor module 204, a camera module 205, and a light-emitting device 206 may be included to be aligned with the recess or opening. In an embodiment (not shown), at least one or more of an audio module 214, a sensor module 204, a camera module 205, a fingerprint sensor (not shown), and a light-emitting element 206 may be included at the back of the screen display region of the display 220. In an embodiment (not shown), the display 220 may be coupled to or disposed adjacent to a touch detection circuit, a pressure sensor capable of measuring the intensity (pressure) of touch, and/or a digitizer that detects a magnetic field-type stylus pen. The audio modules 203, 207, and 214 may include a microphone hole 203 and speaker holes 207 and 214. A microphone for acquiring external sound may be disposed inside the microphone hole 203, and in an embodiment, a plurality of microphones may be disposed to detect the direction of sound. The speaker holes 207 and 214 may include an external speaker hole 207 and a call receiver hole 214. In an embodiment, the speaker holes 207 and 214 and the microphone hole 203 may be implemented as one hole, or a speaker (e.g., a piezo speaker) may be included without the speaker holes 207 and 214.

The key input device 217 may be disposed on the lateral surface 210C of the housing 210. In an embodiment, the electronic device 101 may exclude entirety or some of the key input device 217 mentioned above, and the excluded key input device 217 may be implemented in other forms such as soft keys on the display 220.

For example, the light-emitting device 206 may be disposed on the first surface 210A of the housing 210. For example, the light-emitting device 206 may provide state information of the electronic device 101 in the form of light. In an embodiment, the light-emitting device 206 may provide a light source that is linked to, for example, the operation of the camera module 205. The light-emitting device 206 may include, for example, an LED, an IR LED, and a xenon lamp.

The connector holes 208 and 209 may include a first connector hole 208 capable of receiving a connector (for example, a USB connector) for transmitting and receiving power and/or data to and from an external electronic device, and/or a second connector hole (e.g., earphone jack) 209 capable of receiving a connector for transmitting and receiving audio signals to and from an external electronic device.

According to an embodiment of the disclosure, the electronic device 101 may include cap 500. The cap 500 may be at least partially non-conductive. The cap 500 may be disposed in the side wall structure 310. The cap 500 may have a shape extending long in the longitudinal direction (e.g., the Y-axis direction) of the side wall structure 310. The outer surface of the cap 500 may be exposed to the outside of the electronic device 101.

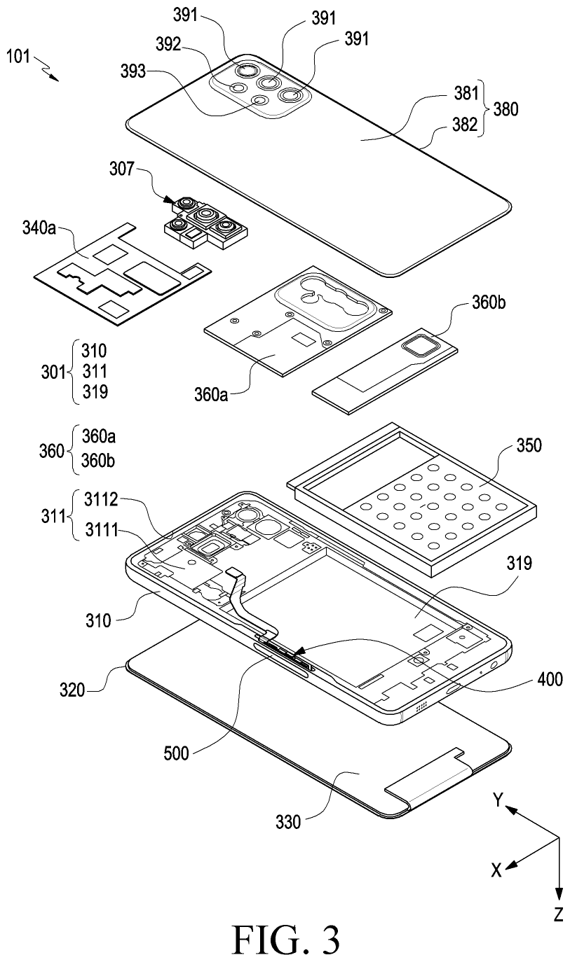

FIG. 3 is an exploded perspective view illustrating the rear of an electronic device according to various embodiments.

Referring to FIG. 3, the electronic device 101 (e.g., the electronic device 101 in FIG. 1 or 2) may include a side structure 310, a bottom structure 319, and a first support member 311 (e.g., a bracket), a front plate 320 (e.g., the front plate 202 in FIG. 2), a display 330 (e.g., the display 220 in FIG. 2), at least one printed circuit board (or substrate assembly) 340a, a battery 350, a second support member 360 (e.g., a rear case), a camera assembly 307, and a rear plate 380. According to an embodiment, the electronic device 101 may exclude at least one (e.g., the first support member 311 or the second support member 360) of the elements or may further include other elements. At least one of the elements of the electronic device 101 may be the same as or similar to at least one of the elements of the electronic device 101 in FIG. 1 or 2, and redundant descriptions thereof will be omitted below.

At least a portion of the first support member 311 may be provided in a flat shape. In an embodiment, the first support member 311 may be disposed inside the electronic device 101 and connected to the side structure 310 or may be formed integrally with the side structure 310. The first support member 311 may be formed of, for example, a metal material and/or a non-metal (e.g., polymer) material. In the case where the first support member 311 is at least partially made of a metal material, the side structure 310 or a portion of the first support member 311 may function as an antenna. The first support member 311 may have one side to which the display 330 is coupled and the other side to which the printed circuit board 340a is coupled. The printed circuit board 340a may have a processor, memory, and/or interface mounted thereto. The processor may include, for example, one or more of a central processing unit, an application processor, a graphics processing unit, an image signal processor, a sensor hub processor, or a communication processor.

The first support member 311 may be referred to as a “support member”. The housing 301 may include a support member 311. The support member 311 may face the front plate 320. The support member 311 may face the rear plate 380. The support member 311 may be coupled to the front plate 320 or the rear plate 380 by an adhesive member. The support member 311 may be made of reinforced plastic or metal.

The support member 311 may include a support body 3111. The support body 3111 may have a flat shape. The support body 3111 may provide a space where the battery 350 or the printed circuit board 340a is disposed.

The support member 311 may include an end portion 3112. The end portion 3112 may be integrated with the support body 3111. The end portion 3112 may be formed along the perimeter of the support body 3111. The end portion 3112 may extend along the perimeter of the side structure 310. The end portion 3112 may be integrated with the side structure 310.

The front plate 320 may be coupled to the support member 311 by an adhesive member. The front plate 320 may be referred to as a “cover” or “front cover”. The rear plate 380 may be referred to as a “cover” or “rear cover”. The cover 380 may face the support member 311. The cover 380 may be made of reinforced plastic or tempered glass laminated with a film.

The cover 380 may include a cover body 381. The cover body 381 may have a flat shape. The cover body 381 may face the support body 3111.

The cover 380 may include a cover edge 382. The cover edge 382 may be integrated with the cover body 381. The cover edge 382 may extend along the direction in which the end portion 3112 of the support member 311 extends. The cover edge 382 may face the end portion 3112 of the support member 311.

According to an embodiment, the first support member 311, the side structure 310, and the bottom structure 319 may be combined and referred to as a front case or housing 301. According to an embodiment, the housing 301 may be generally understood as a structure for accommodating, protecting, or disposing the printed circuit board 340a or the battery 350.

According to an embodiment, the housing 301 may include a bottom structure 319. The side structure 310 may be connected to the bottom structure 319. The side structure 310 may protrude from the edge of the bottom structure 319. The bottom structure 319 and the side structure 310 may form a space for accommodating electronic components (e.g., the battery 350) inside the electronic device 101.

In an embodiment, it may be understood that the housing 301 includes a structure that may be visually or tactilely recognized by the user on the exterior of the electronic device 101, such as the side structure 310, the front plate 320, and/or the rear plate 380. The housing 301 may include the side structure 310, the first support member 311, the front plate 320, and the rear plate 380.

In an embodiment, the first support member 311 may be disposed between the front plate 320 (e.g., the first surface 210A in FIG. 1) and the rear plate 380 and may function as a structure for placing electrical/electronic components such as the printed circuit board 340a or the camera assembly 307.

The memory may include, for example, volatile memory or non-volatile memory.

The interface may include, for example, a high-definition multimedia interface (HDMI), a universal serial bus (USB) interface, an SD card interface, and/or an audio interface. For example, the interface may electrically or physically connect the electronic device 101 to an external electronic device and may include a USB connector, an SD card/MMC connector, or an audio connector.

The second support member 360 may include, for example, an upper support member 360a and a lower support member 360b. In an embodiment, the upper support member 360a may be disposed to surround a printed circuit board (e.g., the first circuit board 340a) together with a portion of the first support member 311. For example, the upper support member 360a of the second support member 360 may be disposed to face the first support member 311 with the first circuit board 340a interposed therebetween. Circuit devices (e.g., processors, communication modules, or memory) implemented in the form of integrated circuit chips or various electrical/electronic components may be disposed on the printed circuit board 340a, and depending on the embodiment, the printed circuit board 340a may be provided with an electromagnetic shielding environment from the second support member 360. In an embodiment, the lower support member 360b may be utilized as a structure on which electrical/electronic components such as a speaker module and an interface (e.g., a USB connector, an SD card/MMC connector, or an audio connector) are disposed. In an embodiment, electrical/electronic components such as speaker modules and interfaces (e.g., a USB connector, an SD card/MMC connector, or an audio connector) may be disposed on additional printed circuit boards, which is not shown. For example, the lower support member 360b may be disposed to surround the additional printed circuit board together with another portion of the first support member 311. A speaker module or interface disposed on the additional printed circuit board (not shown) or the lower support member 360b may be disposed corresponding to the audio module 207 or the connector holes 208 and 309 in FIG. 1.

The battery 350 is a device for supplying power to at least one element of the electronic device 101 and may include, for example, a non-rechargeable primary battery, a rechargeable secondary battery, or a fuel cell. The battery 350 may be supported by the bottom structure 319. At least a portion of the battery 350 may be disposed, for example, substantially on the same plane as the printed circuit board 340a. The battery 350 may be disposed integrally inside the electronic device 101, or may be disposed to be detachable from the electronic device 101.

According to an embodiment, the camera assembly 307 may include at least one camera module. The camera assembly 307 (or at least one camera module) inside the electronic device 101 may receive at least some of the light incident through the optical hole or camera windows 391, 392, and 393. In an embodiment, the camera assembly 307 may be disposed on the first support member 311 at a position close to the printed circuit board 340a. In an embodiment, the camera module(s) of the camera assembly 307 may be generally aligned with any one of the camera windows 391, 392, and 393 and at least partially surrounded by the second support member 360 (e.g., the upper support member 360a).

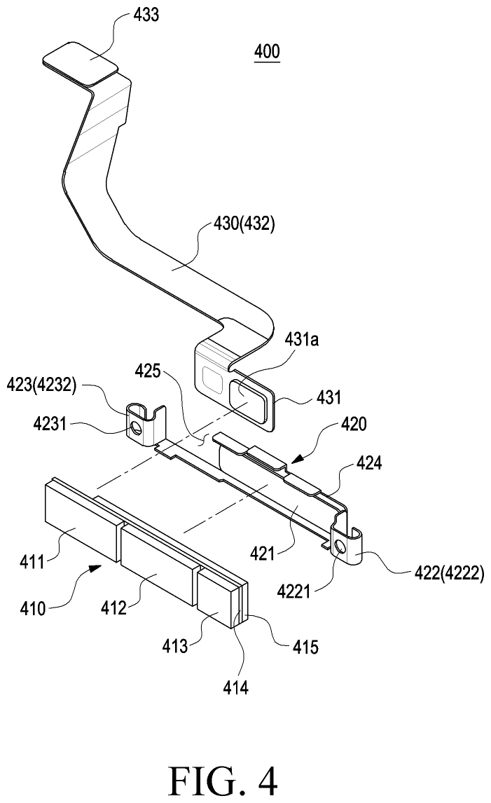

According to an embodiment of the disclosure, the electronic device 101 may include an antenna assembly 400. The antenna assembly 400 may be disposed on the side structure 310 of the housing 301. The antenna assembly 400 may include an antenna element (e.g., the antenna elements 411, 412, and 413 in FIG. 4) that receives or generates radio waves. Radio waves generated from the antenna element may propagate to the outside of the electronic device 101 through the cap 500. Additionally, the antenna element may receive radio waves from the outside of the electronic device 101 through the cap 500.

FIG. 4 is an exploded perspective view illustrating an antenna assembly 400 according to various embodiments. Referring to FIG. 4, according to an embodiment of the disclosure, the antenna assembly 400 may include an antenna module (e.g., including at least one antenna) 410 (e.g., the antenna module 197 in FIG. 1).

According to an embodiment of the disclosure, the antenna module 410 may include a base board 414 connected to a flexible circuit board 430. A plurality of antenna elements 411, 412, and 413 may be mounted on one side of the base board 414. At least one chip 415 may be mounted on the other side of the base board 414.

According to an embodiment of the disclosure, the antenna module 410 may include a plurality of antenna elements 411, 412, and 413 that form directional beams. The plurality of antenna elements 411, 412, and 413 may be disposed on one side of the base board 414 or inside the base board 414. As an example, the plurality of antenna elements 411, 412, and 413 may be a dipole antenna array and/or a patch antenna array.

According to an embodiment of the disclosure, the chip 415 may include a radio frequency integrate circuit (RFIC), and/or a power management integrate circuit (PMIC). The RFIC may be configured to process signals in a selected frequency band, which are transmitted/received through the antenna elements 411, 412, and 413. The PMIC may receive electricity from a power source and provide necessary power to various elements (e.g., the RFIC or the antenna elements 411, 412, and 413) on the antenna module 410.

According to an embodiment of the disclosure, the antenna assembly 400 may include a bracket 420 on which the antenna module 410 is mounted. The bracket 420 may be disposed inside the electronic device 101. The bracket 420 may be disposed inside the side wall 310 of the electronic device 101.

According to an embodiment of the disclosure, the bracket 420 may include a seating portion 424 that supports the antenna module 410. The seating portion 424 may have a shape extending long along the side wall 310.

According to an embodiment of the disclosure, the antenna module 410 may be bonded to the seating portion 424 through an adhesive member 421. The adhesive member 421 may be disposed between the antenna module 410 and the seating portion 424. As an example, the adhesive member 421 may be a double-sided tape.

According to an embodiment of the disclosure, the seating portion 424 may include a connection hole 425. The FPCB 430 and the antenna module 410 may be connected through the connection hole 425. The connection hole 425 may be located between the two coupling portions 422 and 423.

According to an embodiment of the disclosure, the bracket 420 may include one or more (e.g., two) coupling portions 422 and 423. The coupling portions 422 and 423 may be connected to the lateral side of the seating portion 424. The coupling portions 422 and 423 may extend from the seating portion 424.

According to an embodiment of the disclosure, the coupling portions 422 and 423 may include coupling holes 4221 and 4231 to which the cap 500 is coupled. The coupling portions 422 and 423 may include bent portions 4222 and 4232.

According to an embodiment of the disclosure, the coupling portions 422 and 423 may include a first coupling portion 422 connected to one side of the seating portion 424 and a second coupling portion 423 connected to the other side. The second coupling portion 423 may be located closer to the flexible printed circuit board (FPCB) 430 than the first coupling portion 422.

According to an embodiment of the disclosure, the first coupling portion 422 may include a first coupling hole 4221 and a first bent portion 4222. The second coupling portion 423 may include a second coupling hole 4231 and a second bent portion 4232. The first bent portion 4222 and the second bent portion 4232 may be bent toward the seating portion 424.

According to an embodiment of the disclosure, the antenna assembly 400 may include an FPCB 430 that electrically connects the antenna module 410 and the printed circuit board 340a (e.g., FIG. 3) disposed inside the housing 301. The FPCB 430 may include a connector 431a electrically connected to the base board 414 and a plate 431 on which the connector 431a is disposed. The FPCB 430 may include a flexible portion 432 that may bend or warp. The FPCB 430 may include a connector 433 that is electrically connected to the printed circuit board 340a (e.g., FIG. 3) disposed inside the housing 301.

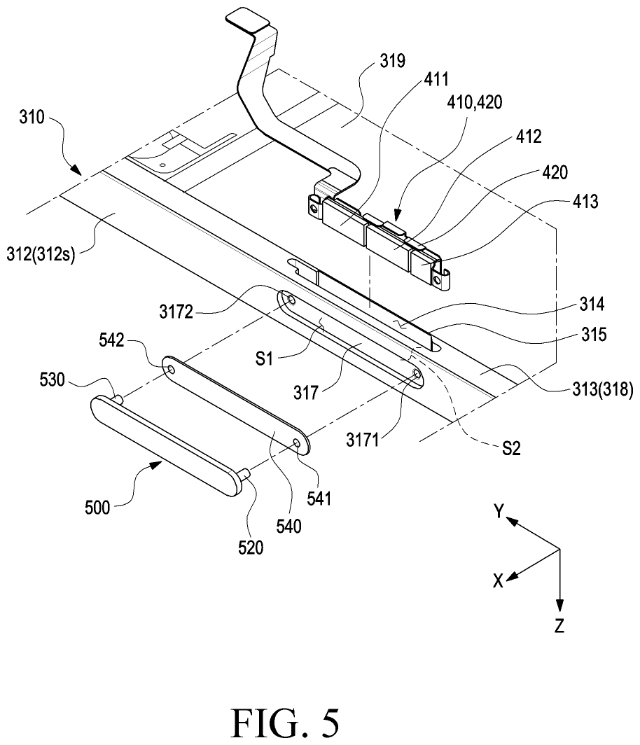

FIG. 5 is an exploded perspective view of an antenna assembly 400 and a cap 500 according to various embodiments.

Referring to FIG. 5, according to an embodiment of the disclosure, the side wall 310 may include a recess 317 formed to be recessed from a portion of the outer surface 312s. The recess 317 may be recessed inward from the outer surface 312s of the side wall 310. A first space S1 may be formed between the recess 317 and the outer surface 312s of the side wall 310. The recess 317 may partially define the first space S1.

According to an embodiment of the disclosure, the recess 317 may be at least partially non-conductive. As an example, the entirety of the recess 317 may be formed of a non-conductive material. As another example, only the region of the recess 317, which corresponds to the antenna elements 411, 412, and 413, may be formed of a non-conductive material. The recess 317 may be referred to as a non-conductive portion 317 of the side wall 310.

According to an embodiment of the disclosure, the recess 317 may be part of the side wall 310 of the housing 301. The antenna elements 411, 412, and 413 of the antenna module 400 may receive signals from the outside of the electronic device 101 or transmit signals to the outside of the electronic device 101 through the recess 317. According to an embodiment of the disclosure, the side wall 310 may include a radiation hole connecting the first space S1 and the second space S2. The non-conductive portion 317 may be disposed in the radiation hole. As an example, the side wall 310 may be formed of a metal material, excluding the non-conductive portion 317, to reinforce the rigidity of the electronic device, and the radiation hole into which the non-conductive portion 317 is inserted may be formed in the metal portion. The plurality of antenna elements 411, 412, and 413 may transmit radio waves toward the radiation hole into which the non-conductive portion 317 is inserted.

According to an embodiment of the disclosure, the non-conductive portion 317 may include a first through-hole 3171 through which a first protruding portion 520 passes and a second through-hole 3172 through which a second protruding portion 530 passes. The first through-hole 3171 may face the first coupling hole 4221 of the bracket 420. The second through-hole 3172 may face the second coupling hole 4231 of the bracket 420.

According to an embodiment of the disclosure, the side wall 310 may include a frame portion 312 surrounding the non-conductive portion 317. The non-conductive portion 317 may be recessed inward from the outer surface 312s of the frame portion 312. The non-conductive portion 317 may be coupled to the frame portion 312. The non-conductive portion 317 may be bonded to the frame portion 312. According to an embodiment of the disclosure, the frame portion 312 may be exposed to the outside of the electronic device 101. The frame portion 312 may form the exterior of the electronic device 101. The non-conductive portion 317 may not be exposed to the outside of the electronic device 101. As an example, the frame portion 312 may be formed of a metal material to ensure the rigidity of the electronic device 101.

According to an embodiment of the disclosure, the side wall 310 may include a second space S2 where the bracket 420 is mounted. The second space S2 may be located opposite the first space S1 with respect to the non-conductive portion 317. The second space S2 and the first space S1 may be located on both sides of the non-conductive portion 317.

According to an embodiment of the disclosure, the second space S2 may communicate with the outside of the side wall 310 through a guide hole 314. As an example, the second space S2 may communicate with the rear of the side wall 310 through the guide hole 314. The guide hole 314 may be an entrance through which the bracket 420 on which the antenna module 410 is mounted enters and exits. The guide hole 314 may have a shape corresponding to the bracket 420 on which the antenna module 410 is mounted. The guide hole 314 may be a slot extending along the side wall 310. The guide hole 314 may be referred to as a slot 314 or a guide slot 314.

According to an embodiment of the disclosure, the guide hole 314 may be formed on the adhesion surface 313 of the side wall 310. The front plate 320 (e.g., FIGS. 2 and 3) or the rear plate 380 (e.g., FIG. 3) may be bonded to the adhesion surface 313. FIG. 5 shows, as an example, a case where the adhesion surface 313 is the rear surface of the side wall 310, and the rear plate (or cover) 380 (e.g., FIG. 3) is bonded thereto. However, unlike what is shown in FIG. 5, the adhesion surface 313 may be the front surface of the side wall 310, and the front plate 320 (e.g., FIGS. 2 and 3) may be bonded thereto. The adhesion surface 313 may be referred to as a “rear surface 313” of the side wall 310.

Referring to FIG. 5, according to an embodiment of the disclosure, the electronic device 101 may include an adhesive member 318 disposed between the cover 380 and the adhesion surface 313. For example, the adhesive member 318 may be a double-sided tape or an adhesive that is applied to the adhesion surface 313 and then hardened through a special process such as radiating ultraviolet rays thereon.

According to an embodiment of the disclosure, the electronic device 101 may include a cap 500 disposed in the first space S1. The cap 500 may include a non-conductive material. The cap 500 may cover the recess 317 of the side wall 310. The non-conductive cap 500 may face the recess 317 of the side wall 310.

According to an embodiment of the disclosure, the cap 500 may be bonded to the non-conductive portion 317 through an adhesive member 540. The adhesive member 540 may be disposed between the cap 500 and the non-conductive portion 317. The adhesive member 540 may include holes 541 and 542 through which the protruding portions 520 and 530 pass. The adhesive member 540 may include a first hole 541 through which the first protruding portion 520 passes and a second hole 542 through which the second protruding portion 530 passes.

According to an embodiment of the disclosure, the cap 500 may include one or more (e.g., two) protruding portions 520 and 530. After the bracket 420 is disposed inside the second space S2, the cap 500 may be inserted into the first space S1 and fastened to the bracket 420.

According to an embodiment of the disclosure, the first protruding portion 520 penetrates the first hole 541 of the adhesive member 540 and the first through-hole 3171 of the non-conductive portion 317. The first protruding portion 520 may be inserted into the first coupling hole 4221 of the bracket 420. The first protruding portion 520 may penetrate the first coupling hole 4221 of the bracket 420. In addition, the second protruding portion 530 may pass through the second hole 542 of the adhesive member 540, the second through-hole 3172 of the non-conductive portion 317, and the second coupling hole 4231 of the bracket 420.

According to an embodiment of the disclosure, the holes 541 and 542 of the adhesive member 540 may be positioned to correspond to the through-holes 3171 and 3172 of the non-conductive portion 317. The adhesive member 540 may surround the first through-hole 3171 and the second through-hole 3172 of the non-conductive portion 317. Therefore, the adhesive member 540 may prevent and/or block foreign substances and/or liquid from flowing from outside the electronic device 101 into the electronic device 101 through the first through-hole 3171 and the second through-hole 3172.

According to an embodiment of the disclosure, the first and second protruding portions 520 and 530 may be coupled to the first and second coupling holes 4221 and 4231 to restrict the bracket 420 to which the antenna module 410 is mounted from moving inside the second space S2.

According to an embodiment of the disclosure, the non-conductive portion 317 may be located between the cap 500 and the antenna module 410. The non-conductive portion 317 may face the antenna elements 411, 412, and 413 of the antenna module 410. The antenna elements 411, 412, and 413 may transmit radio waves toward the first space S1. The antenna elements 411, 412, and 413 may receive radio waves from the outside of the electronic device 101 through the cap 500 and the non-conductive portion 317.

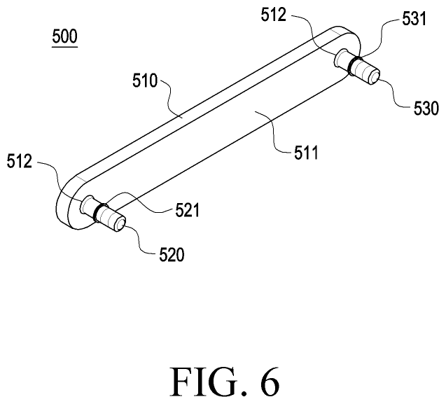

FIG. 6 is a perspective view of a cap 500 according to various embodiments. Referring to FIG. 6, according to an embodiment of the disclosure, the cap 500 may include a board 510 extending long along the side wall 310. The board 510 may have a shape corresponding to the first space S1 of the side wall 310.

According to an embodiment of the disclosure, the outer surface of the board 510 may be exposed to the outside of the electronic device 101. The inner surface 511 of the board 510 may face the non-conductive portion 317 of the side wall 310. The outer surface of the board 510 may form a continuous surface with the outer surface 312s of the side wall 310.

According to an embodiment of the disclosure, the protruding portions 520 and 530 may be connected to the inner lateral surface 511 of the board 510 facing the non-conductive portion 317. The portions 512 where the protruding portions 520 and 530 are connected to the inner surface 511 of the board 510 may be referred to as connection portions 512. The protruding portions 520 and 530 may protrude from the inner surface 511 of the board 510.

According to an embodiment of the disclosure, the cap 500 may include sealers 521 and 531. The sealers 521 and 531 may be disposed on the lateral surfaces of the protruding portion 520 and 530. The sealer 521 and 531 may surround the lateral surfaces of the protruding portion 520 and 530. The sealers 521 and 531 may protrude from the lateral surfaces of the protruding portions 520 and 530. The sealers 521 and 531 may have elasticity. The sealers 521 and 531 may seal the holes 3171 and 3172 of the non-conductive portion 317.

According to an embodiment of the disclosure, the cap 500 may be at least partially non-conductive. As an example, the board 510 and the protruding portions 520 and 530 may be formed integrally of a non-conductive material (e.g., a resin-based material). As another example, the board 510 may be made of a non-conductive material, and the protruding portions 520 and 530 may be made of a material different from that of the board 510.

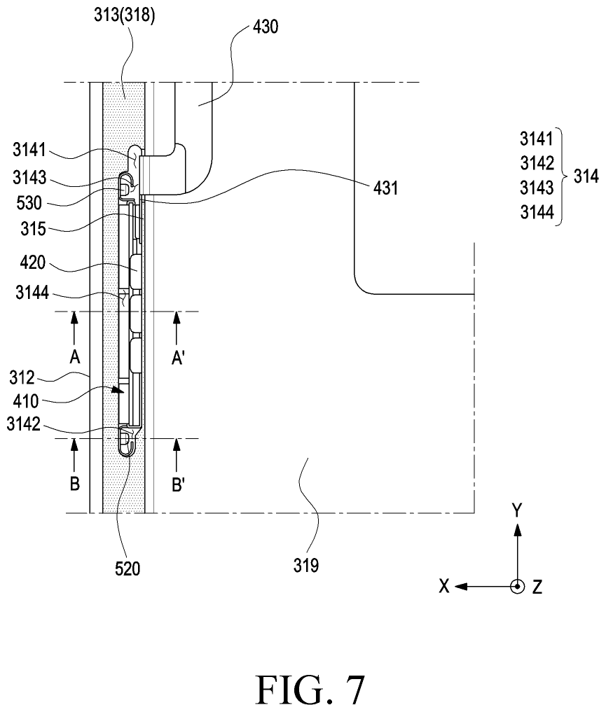

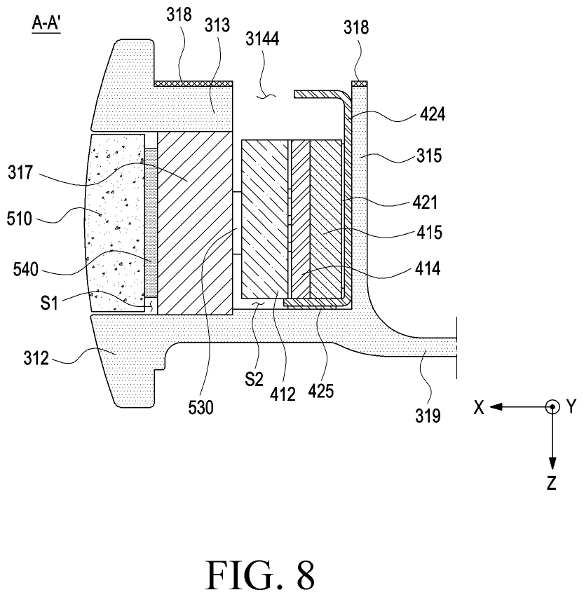

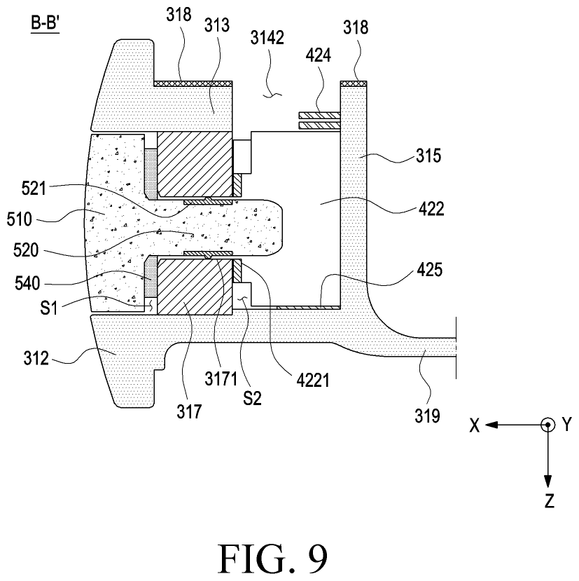

FIG. 7 is a diagram illustrating a rear view of a portion of an electronic device 101 according to various embodiments. FIG. 8 is a cross-sectional view taken along line A-A′ in FIG. 7 according to various embodiments. FIG. 9 is a cross-sectional view taken along line B-B′ in FIG. 7 according to various embodiments.

Referring to FIG. 7, according to an embodiment of the disclosure, the side wall 310 may include an inner portion 315 supporting the bracket 420. The inner portion 315 may partially define the second space S2 (see FIG. 5). The bracket 420 on which the antenna module 410 is mounted may be disposed between the non-conductive portion 317 and the inner portion 315. The inner portion 315 may partially define the guide hole 314.

The inner portion 315 may be connected to the frame portion 312. One side of the inner portion 315 may form a continuous surface with the adhesion surface 313. The adhesive member 318 may be disposed on one side of the inner portion 315 that forms a continuous surface with the adhesion surface 313.

According to an embodiment of the disclosure, the frame portion 312 and the inner portion 315 may form a guide hole 314. The guide hole 314 may include a plurality of regions 3141, 3142, 3143, and 3144. The plurality of regions 3141, 3142, 3143, and 3144 may be arranged in the longitudinal direction (e.g., the Y-axis direction) of the side wall 310.

Each of the regions 3141, 3142, 3143, and 3144 may be partially defined by the frame portion 312 and/or the inner portion 315. The guide hole 314 may include a first region 3143, a second region 3141, a third region 3142, and a fourth region 3144.

The plurality of regions 3141, 3142, 3143, and 3144 of the guide hole 314 may be distinguished from each other by ordinal numbers. Ordinal numbers such as first, second, or the like are used only for the purpose of distinguishing one element from another element and may be used interchangeably depending, for example, on the sequence of explanation, and do not limit the elements.

According to an embodiment of the disclosure, the second region 3141 and the third region 3142 may be located at both ends of the guide hole 314 in the longitudinal direction (e.g., the Y-axis direction) of the side wall 310, and the first region 3143 and the fourth region 3144 may be located between the second region 3141 and the third region 3142.

According to an embodiment of the disclosure, the second region 3141 may be connected to the first region 3143. The second region 3141 may be located at one end of the guide hole 314. The plate 431 of the FPCB 430 may be inserted into the second space S2 through the second region 3141. The plate 431 of the FPCB 430 may be inserted into the second space S2 through the second region 3141 and the third region 3142 of the guide hole 314.

According to an embodiment of the disclosure, the second region 3141 may have a width less than the width of the first region 3143. For example, the width of the second region 3141 defined in the protruding direction (e.g., the −X-axis direction) of the protruding portions 520 and 530 of the cap 500 may be less than the width of the first region 3143.

According to an embodiment of the disclosure, the third region 3142 may be connected to the fourth region 3144. The third region 3142 may be located at the other end of the guide hole 314. The third region 3142 may have a shape corresponding to the first coupling portion 422 of the bracket 420. The first coupling portion 422 of the bracket 420 may be inserted into the second space S2 through the third region 3142. The first coupling portion 422 of the bracket 420 may be moved to the outside of the second space S2 through the third region 3142.

According to an embodiment of the disclosure, the third region 3142 may have a width less than the width of the fourth region 3144. For example, the width of the third region 3142 defined in the protruding direction (e.g., the −X-axis direction) of the protruding portions 520 and 530 of the cap 500 may be less than the width of the fourth region 3144.

According to an embodiment of the disclosure, the first region 3143 may be connected to the second region 3141 and the fourth region 3144. The first region 3143 may be located between the second region 3141 and the fourth region 3144.

According to an embodiment of the disclosure, the first region 3143 may have a shape corresponding to the second coupling portion 423 of the bracket 420. The second coupling portion 423 of the bracket 420 may be inserted into the second space S2 through the first region 3143. The second coupling portion 423 of the bracket 420 may be moved to the outside of the second space S2 through the first region 3143.

According to an embodiment of the disclosure, the fourth region 3144 may be connected to the third region 3142 and the first region 3143. The fourth region 3144 may be located between the third region 3142 and the first region 3143.

According to an embodiment of the disclosure, the fourth region 3144 may have a shape corresponding to the seating portion 424 of the bracket 420. The seating portion 424 of the bracket 420 may be inserted into the second space S2 through the fourth region 3144. The seating portion 424 of the bracket 420 may be moved to the outside of the second space S2 through the fourth region 3144.

Referring to FIGS. 7 and 8, according to an embodiment of the disclosure, the bracket 420 (see FIG. 4) and the antenna module 410 (see FIG. 4) may be accommodated in the second space S2. According to an embodiment of the disclosure, the cap 500 (see FIG. 5) may be accommodated in the first space S1.

According to an embodiment of the disclosure, the non-conductive portion 317 of the side wall 310 may be located between the board 510 of the cap 500 and the plurality of antenna elements 411, 412, and 413. The antenna elements 411, 412, and 413 may transmit radio waves to the outside of the electronic device 101 through the non-conductive member 317 or receive radio waves from the outside of the electronic device 101 through the non-conductive member 317.

According to an embodiment of the disclosure, the bracket 420 on which the antenna module 410 is mounted may enter and exit through the fourth region 3144 of the guide hole 314. The non-conductive portion 317 of the side wall 310 may be located between the first space S1 and the second space S2.

Referring to FIGS. 7 and 9, according to an embodiment of the disclosure, the first protruding portion 520 of the cap 500 (see FIG. 5) may pass through the first through-hole 3171 and the first coupling hole 4221. Sealers 521 and 531 (e.g., see FIG. 6) may be disposed on the lateral surfaces of the protruding portion 520 and 530 (e.g., see FIG. 6).

FIG. 9 shows the first protruding portion 520. A description of the first protruding portion 520 and the sealer 521 shown in FIG. 9 may be equally applied to the second protruding portion 530 and the sealer 531 shown in FIG. 6.

The sealer 521 according to an embodiment of the disclosure may be disposed on the lateral surface of the protruding portion 520. The sealer 521 may be located in the through-hole 3171 of the non-conductive portion 317. The sealer 521 may come into contact with the inner surface of the non-conductive portion 317 that defines the through-hole 3171. The sealer 521 may seal the space between the lateral surface of the protruding portion 520 inserted into the through-hole 3171 and the inner surface of the non-conductive portion 317 defining the through-hole 3171. According to an embodiment of the disclosure, the protruding portion 520 may pass through the coupling hole 4221. The protruding portion 520 may restrict the bracket 420 from moving in the second space S2. The protruding portion 520 may restrict the bracket 420 from moving out of the second space S2 through the guide hole 314.

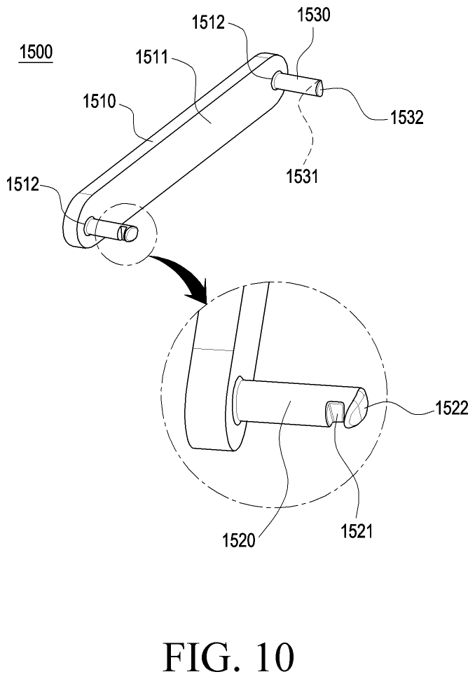

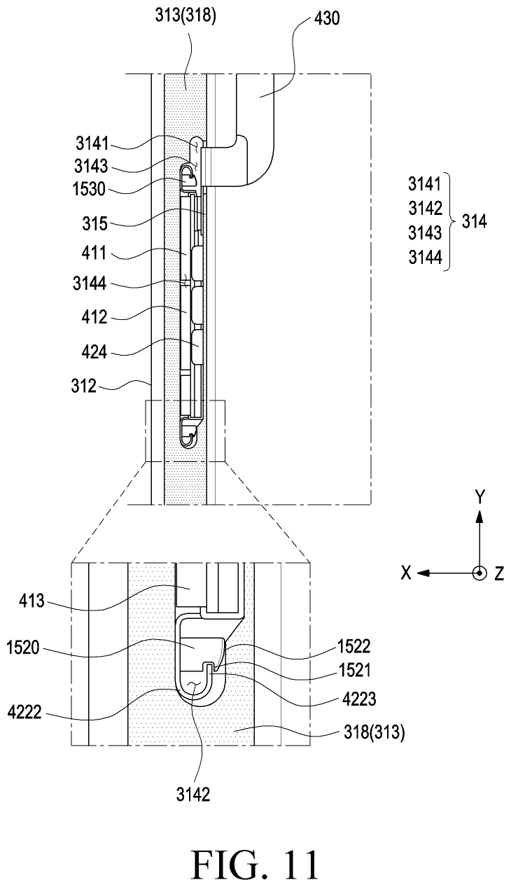

FIG. 10 is a perspective view of a cap 1500 according to various embodiments. FIG. 11 is a diagram illustrating a rear view of a portion of an electronic device 101 according to various embodiments.

The descriptions of the elements (the board 510, the inner surface 511, the connection portions 512, and the protruding portions 520 and 530) made with reference to FIG. 6 may be equally applied to the same elements (a board 1510, an inner surface 1511, connection portions 1512, and protruding portions 1520 and 1530) shown in FIG. 10 as long as they are compatible.

Referring to FIG. 10, according to an embodiment of the disclosure, the protruding portions 1520 and 1530 may include grooves 1521 and 1531. The grooves 1521 and 1531 may be formed on the lateral surfaces of the protruding portions 1520 and 1530. The grooves 1521 and 1531 may extend along the circumferences of the protruding portions 1520 and 1530. The grooves 1521 and 1531 may be located closer to the ends of the protruding portions 1520 and 1530, instead of the connection portions 1512 of the protruding portions 1520 and 1530.

According to an embodiment of the disclosure, a first groove 1521 may be formed on the lateral surface of the first protruding portion 520, and a second groove 1531 may be formed on the lateral surface of the second protruding portion 530. The first groove 1521 and the second groove 1531 may face opposite directions. The first groove 1521 and the second groove 1531 may face each other. The shapes of the first groove 1521 and the second groove 1531 may be symmetrical to each other.

Referring to FIG. 10, according to an embodiment of the disclosure, the protruding portion 1520 and 1530 may include inclined surfaces 1522 and 1532. The inclined surface 1522 and 1532 may be formed at the ends of the protruding portion 1520 and 1530. The inclined surfaces 1522 and 1532 may be inclined downward toward the inner surface 1511 of the cap 1500. The inclined surfaces 1522 and 1532 may be connected to the edges of the grooves 1521 and 1531. The inclined surface 1522 and 1532 may be a convex curved surface in the protrusion directions of the protruding portion 1520 and 1530.

Referring to FIGS. 10 and 11, according to an embodiment of the disclosure, the bracket 420 may include a bent portion 4222. The bent portion 4222 may be bent toward the protruding portion 1520. The end 4223 of the bent portion 4222 may be located inside the groove 1521. As the protruding portion 1520 is inserted, the inclined surface 1522 of the protruding portion 1520 and the end 4223 of the bent portion 4222 may come into contact with each other. During the process of inserting the protruding portion 1520, the bent portion 4222 may be elastically deformed. The end 4223 of the bent portion 4222 may slide toward the groove 1521 along the inclined surface 1522 of the protruding portion 1520.

According to an embodiment of the disclosure, when the protruding portion 1520 is inserted, the end 4223 of the bent portion 4222 may be restored by elastic force and inserted into the groove 1521. The groove 1521 may have a shape corresponding to the end 4223 of the bent portion 4222.

Although the relationship between the groove 1521 of the first protruding portion 1520 and the end 4223 of the first bent portion 4222 has been described in FIG. 11, it may also be applied to the coupling relationship between the second protruding portion 1530 and the bracket 420 shown in FIG. 11 in the same manner.

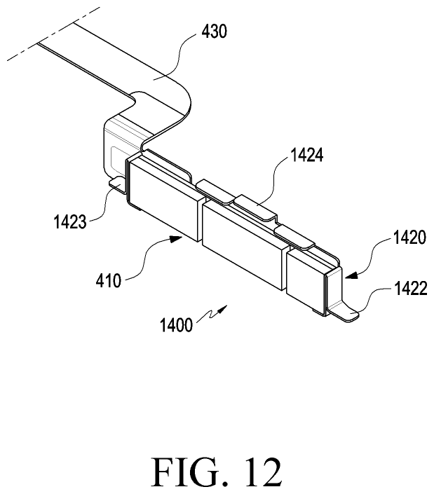

FIG. 12 is a perspective view of an antenna assembly 1400 according to various embodiments. Referring to FIG. 12, according to an embodiment of the disclosure, the antenna assembly 1400 may include an antenna module 410 and a bracket 1420 on which the antenna module 410 is mounted. The description of the seating portion 424 made with reference to FIG. 4 may be equally applied to the seating portion 1424 in the same name shown in FIG. 12 as long as they are compatible.

Referring to FIG. 12, the bracket 1420 according to an embodiment of the disclosure may include a flange portions 1422 and 1423 connected to the seating portion 1424. At least one or more (e.g., two) flange portions 1422 and 1423 may be provided. The flange portions 1422 and 1423 may be connected to both sides of the seating portion 1424.

According to an embodiment of the disclosure, a first flange portion 1422 and a second flange portion 1423 may extend away from each other. For example, the first flange portion 1422 and the second flange portion 1423 may extend in the opposite directions to each other.

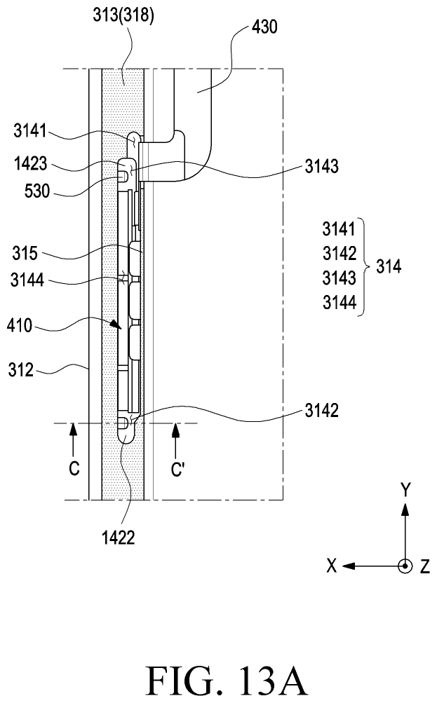

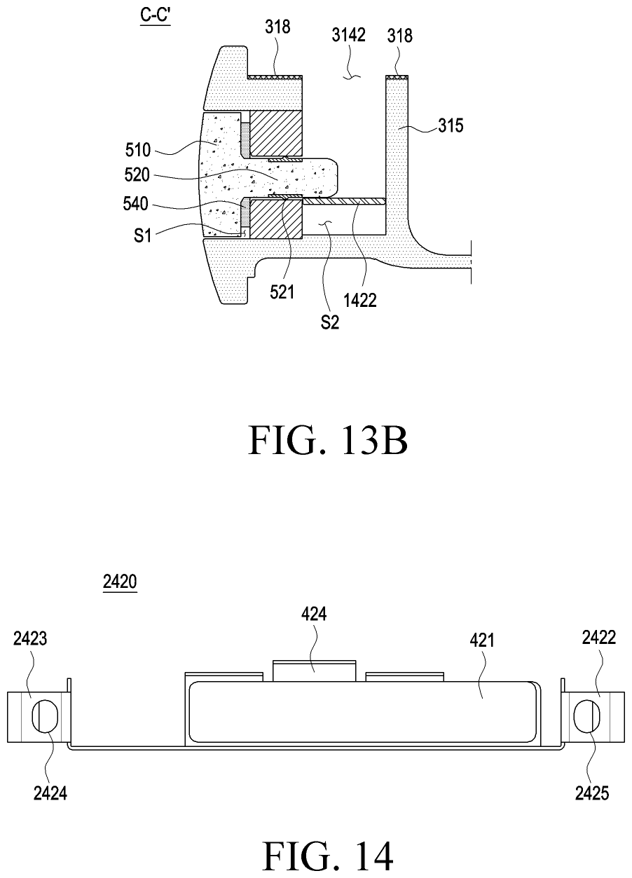

FIG. 13A is a diagram illustrating a rear view of a portion of an electronic device 101 according to various embodiments. FIG. 13B is a cross-sectional view taken along line C-C′ in FIG. 13A according to various embodiments. The description of the plurality of regions 3141, 3142, 3143, and 3144 of the guide hole 314 made with reference to FIG. 7 may be equally applied to the plurality of regions 3141, 3142, 3143, and 3144 of the guide hole 314 in the same name shown in FIG. 13A as long as they are compatible.

Referring to FIGS. 12 and 13A, according to an embodiment of the disclosure, the first region 3143 may have a shape corresponding to the second flange portion 1423 of the bracket 1420. The second flange portion 1423 may be inserted into the second space S2 through the first region 3143. The second flange portion 1423 of the bracket 420 may be moved from the second space S2 to the outside of the second space S2 through the first region 3143.

According to an embodiment of the disclosure, the second region 3141 may have a width less than the width of the first region 3143. For example, the width of the second region 3141 defined in the protruding directions (e.g., the −X-axis direction) of the protruding portions 520 and 530 of the cap 500 may be less than the width of the first region 3143.

According to an embodiment of the disclosure, the third region 3142 may have a shape corresponding to the first flange portion 1422 of the bracket 1420. The first flange portion 1422 of the bracket 1420 may be inserted into the second space S2 through the third region 3142. The first flange portion 1422 of the bracket 420 may be moved from the second space S2 to the outside of the second space S2 through the third region 3142.

According to an embodiment of the disclosure, the third region 3142 may have a width less than the width of the fourth region 3144. For example, the width of the third region 3142 defined in the protruding directions (e.g., the −X-axis direction) of the protruding portions 520 and 530 of the cap 500 may be less than the width of the fourth region 3144.

Referring to FIG. 13A, according to an embodiment of the disclosure, the second flange portion 1423 and the second protruding portion 530 may overlap each other. The second flange portion 1423 and the second protruding portion 530 may overlap each other in the opening direction (e.g., the Z-axis direction) of the guide hole 314. The second flange portion 1423 may be caught by the second protruding portion 530. The second protruding portion 530 may restrict the second flange portion 1423 from leaving the second space S2 through the guide hole 314.

Referring to FIGS. 13A and 13B, according to an embodiment of the disclosure, the first flange portion 1422 and the first protruding portion 520 (e.g., see FIG. 13B) may overlap each other. The first flange portion 1422 and the first protruding portion 520 may overlap each other in the opening direction (e.g., the Z-axis direction) of the guide hole 314. The first flange portion 1422 may be caught by the first protruding portion 520. The first protruding portion 520 may restrict the first flange portion 1422 from leaving the second space S2 through the guide hole 314.

According to an embodiment of the disclosure, the first protruding portion 520 may be adjacent to the top surface of the first flange portion 1422. As an example, when the first protruding portion 520 passes through the non-conductive portion, the end of the first protruding portion 520 may press the upper surface of the first flange portion 1422 downward (e.g., in the Z-axis direction in FIG. 13A). Accordingly, the first protruding portion 520 may restrict the first flange portion 1422 from leaving the second space S2 through the guide hole 314.

FIG. 14 is a diagram illustrating a front view of a bracket 2420 according to various embodiments. The descriptions of the seating portion 424, the coupling portion 422 or 423, the coupling hole 4221 or 4231, and the adhesive member 421 made with reference to FIG. 4 may be equally applied to the seating portion 424, the coupling portion 2422 or 2423, the coupling hole 2424 or 2425, and the adhesive member 421 in the same names shown in FIG. 14 as long as they are compatible.

Referring to FIG. 14, according to an embodiment of the disclosure, the bracket 2420 may include coupling holes 2424 and 2425 in the form of slots. The first coupling hole (2424) may be disposed at the first coupling portion (2423). The second coupling hole (2425) may be disposed at the second coupling portion (2422).

According to an embodiment of the disclosure, the widths of the coupling holes 2424 and 2425 defined in the longitudinal direction of the side wall 310 may be less than the widths of the coupling holes 2424 and 2425 defined in the direction intersecting the longitudinal direction of the side wall 310. As an example, the widths of the coupling holes 2424 and 2425 defined in the longitudinal direction of the side wall 310 may be less than the widths of the coupling holes 2424 and 2425 defined in a direction perpendicular to the longitudinal direction of the side wall 310.

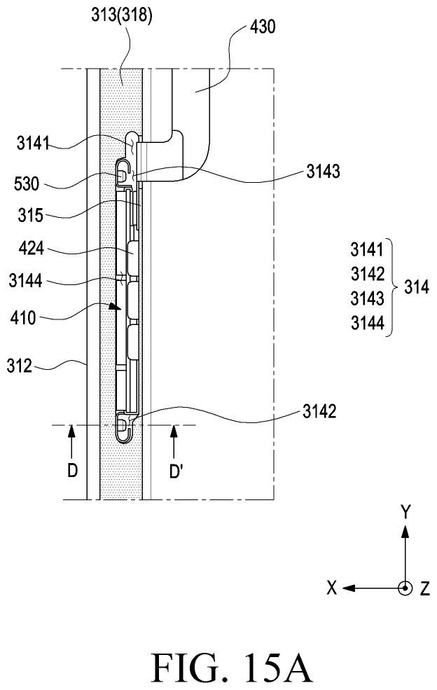

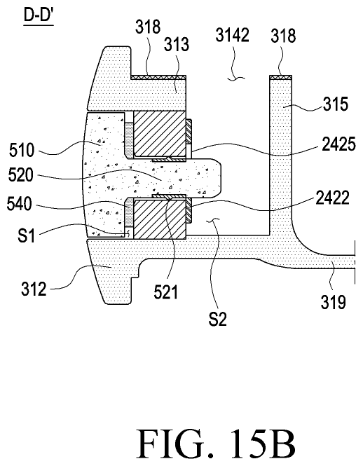

FIG. 15A is a diagram illustrating a rear view of a portion of an electronic device according to various embodiments. FIG. 15B is a cross-sectional view taken along line D-D′in FIG. 15a according to various embodiments.

The description of the plurality of regions 3141, 3142, 3143, and 3144 of the guide hole 314 made with reference to FIG. 7 may be equally applied to the plurality of regions 3141, 3142, 3143, and 3144 of the guide hole 314 in the same name shown in FIG. 15A as long as they are compatible.

Referring to FIGS. 15A and 15B, according to an embodiment of the disclosure, the center of the coupling hole 2425 may be spaced apart from the central axis of the protruding portion 520. The distance from one side of the boundary of the coupling hole 2425 to the lateral surface of the protruding portion 520 may be different from the distance from the other side of the boundary of the coupling hole 2425 to the lateral surface of the protruding portion 520. As an example, one side of the boundary of the coupling hole 2425 may be adjacent to the lateral surface of the protruding portion 520 and may support the lateral surface of the protruding portion 520. The other side of the boundary of the coupling hole 2425 may be spaced apart from the lateral surface of the protruding portion 520 and may provide clearance for smooth penetration of the protruding portion 520.

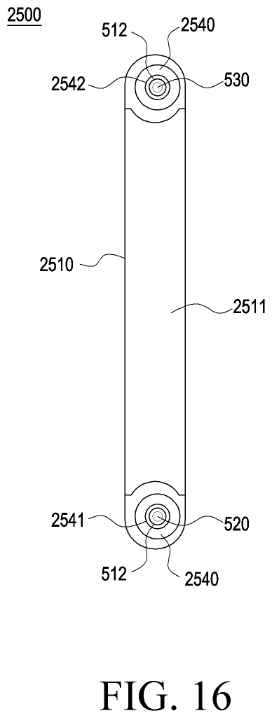

FIG. 16 is a diagram illustrating a rear view of a cap 2500 according to various embodiments.

Referring to FIG. 16, the cap 2500 according to an embodiment of the disclosure may include a board 2510 from which one or more protruding portions 520 and 530 protrude. The board 2510 may extend to be long.

The cap 2500 may include a stepped portion 2511 that is stepped from the board 2510 toward the non-conductive portion 317 (e.g., FIG. 5) of the side wall 310. The stepped portion 2511 may protrude toward the non-conductive portion 317 (e.g., FIG. 5) of the side wall 310. The protruding heights of the protruding portions 520 and 530 of the cap 2500 may be greater than the protruding height of the stepped portion 2511.

According to an embodiment of the disclosure, the stepped portion 2511 may be located between the two protruding portions 520 and 530. The stepped portion 2511 may face the non-conductive portion 317 (e.g., FIG. 5) of the side wall 310. The stepped portion 2511 may come into contact with the non-conductive portion 317 (e.g., FIG. 5) of the side wall 310.

The cap 2500 according to an embodiment of the disclosure may include an adhesive member 2540. The adhesive member 2540 may include holes 2541 and 2542.

The protruding portions 520 and 530 of the cap 2500 may pass through the holes 2541 and 2542 of the adhesive member 2540.

According to an embodiment of the disclosure, the adhesive member 2540 may be disposed between the board 2510 and the non-conductive portion 317 (e.g., FIG. 5) of the side wall 310. The adhesive member 2540 may surround the through-holes 3171 and 3172 (e.g., FIG. 5) of the non-conductive portion 317.

According to an embodiment of the disclosure, the two lateral edges of the stepped portion 2511 may have shapes corresponding to the shape of the adhesive member 2540. Two lateral edges of the stepped portion 2511 may have concave shapes corresponding to the convex shape of the adhesive member 2540.

According to an embodiment of the disclosure, the holes 2541 and 2542 of the adhesive member 2540 may be positioned to correspond to the through-holes 3171 and 3172 (see FIG. 5) of the non-conductive portion 317. The adhesive member 2540 may surround the first through-hole 3171 and the second through-hole 3172 of the non-conductive portion 317. Accordingly, the adhesive member 2540 may prevent and/or block foreign substances and/or liquid from flowing from the outside of the electronic device (e.g., the electronic device 101 in FIG. 3) into the interior of the electronic device 101 through the first through-hole 3171 and the second through-hole 3172.

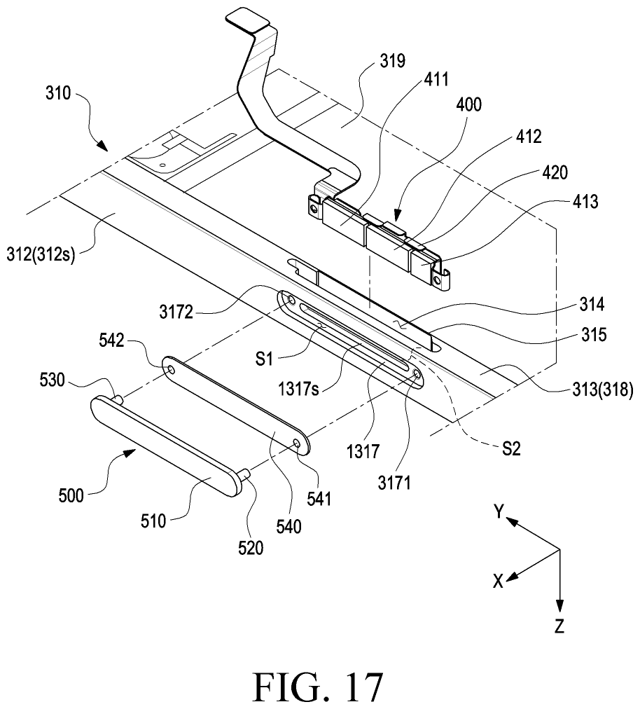

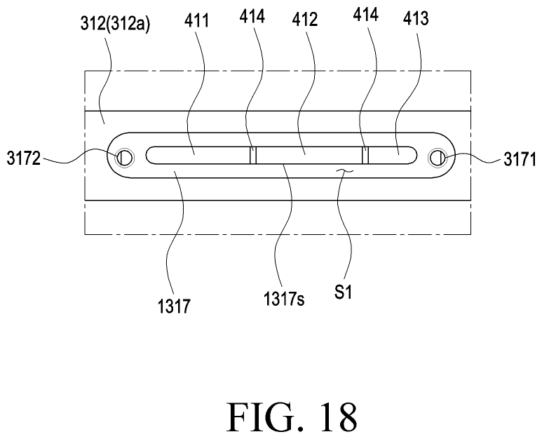

FIG. 17 is an exploded perspective view of an antenna assembly 400 and a cap 500 according to various embodiments. FIG. 18 is an enlarged view of a portion of the side wall 310 shown in FIG. 17 with an antenna 400 assembly disposed on the side wall 310 according to various embodiments.

The description of the recess 317 or the non-conductive portion 317 of the side wall 310 made with reference to FIG. 5 may be applied to the recess 1317 or the non-conductive portion 1317 of the side wall 310 in the same name shown in FIGS. 17 and 18 as long as they are compatible.

Referring to FIG. 17, according to an embodiment of the disclosure, the side wall 310 of the housing 301 (see FIG. 3) may include a recess 1317. The recess 1317 may include one or more through-hole 3171 and 3172 and at least one opening 1317s. The first space S1 and the second space S2 may communicate with each other through the opening 1317s.

According to an embodiment of the disclosure, the through-holes 3171 and 3172 and the opening 1317s may be arranged in the longitudinal direction (e.g., the Y-axis direction) of the recess 1317. The opening 1317s may have the shape of an elongated slot. The opening 1317s may be a slot 1317s extending along the direction in which the antenna elements 411, 412, and 413 are arranged (e.g., the Y-axis direction). The slot 1317s may be a slot 1317s extending along the longitudinal direction (e.g., the Y-axis direction) of the side wall 310.

According to an embodiment of the disclosure, the opening 1317s may be located between the first through-hole 3171 and the second through-hole 3172. As an example, in the case where a plurality of openings 1317s is provided, the openings 1317s may be arranged between the first through-hole 3171 and the second through-hole 3172 along the direction in which the antenna elements 411, 412, and 413 are arranged (e.g., the Y-axis direction).

According to an embodiment of the disclosure, the recess 1317 may be at least partially non-conductive. As an example, the recess 1317 may be formed entirely of a non-conductive material and an opening 1317s may be formed thereon. As another example, only the region (e.g., around the opening 1317s) of the recess 1317, corresponding to the antenna elements 411, 412, and 413, may be formed of a non-conductive material. The recess 1317 may be referred to as a non-conductive portion 1317 of the side wall 310.

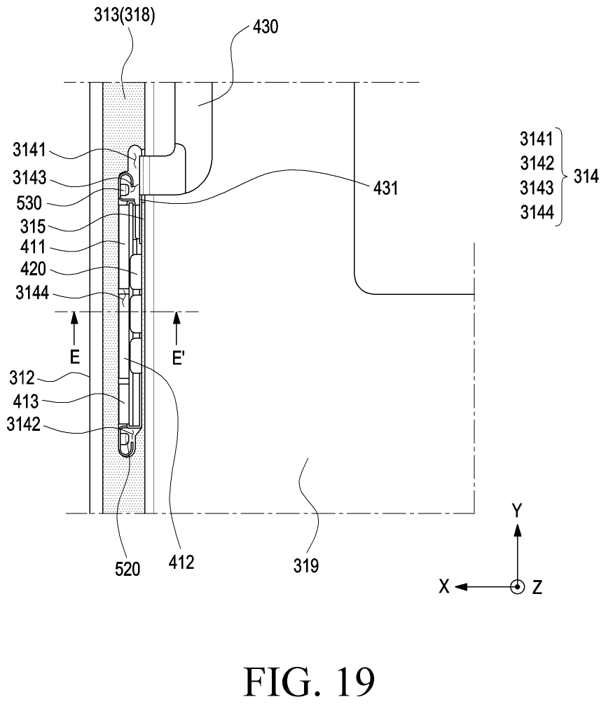

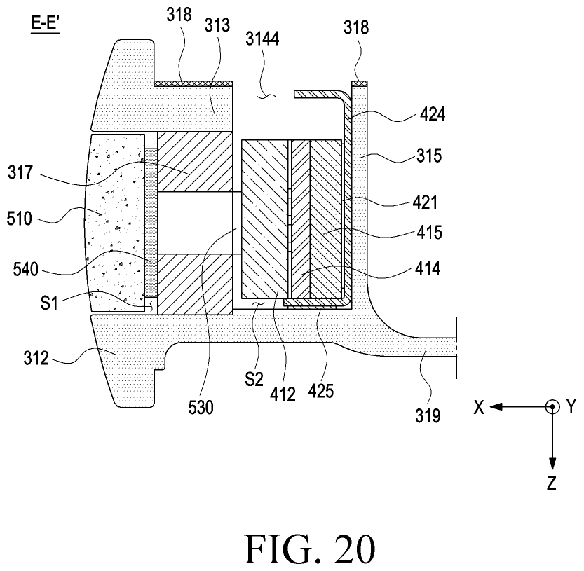

FIG. 19 is a diagram illustrating a rear view of a portion of an electronic device (e.g., the electronic device 101 in FIG. 3) according to various embodiments. FIG. 20 is a cross-sectional view taken along line E-E′ in FIG. 19 according to various embodiments.

The descriptions of the recess 317 or the non-conductive portion 317 of the side wall 310 made with reference to FIGS. 5 to 8 may be equally applied to the recess 1317 or the non-conductive portion 1317 of the side wall 310 in the same name shown in FIG. 20 as long as they are compatible.

Referring to FIGS. 19 and 20, the recess 1317 may be located between the board 510 of the cap 500 and the antenna elements 411, 412, and 413. The opening 1317s of the recess 1317 may be located between the antenna elements 411, 412, and 413 and the board 510 of the cap 500.

According to an embodiment of the disclosure, the antenna elements 411, 412, and 413 may receive signals from the outside of the electronic device 101 or transmit signals to the outside of the electronic device 101 through the recess 1317. The antenna elements 411, 412, and 413 may receive signals from the outside of the electronic device 101 or transmit signals to the outside of the electronic device 101 through the slot 1317s.

According to an embodiment of the disclosure, the adhesive member 540 may be disposed between the recess 1317 and the board 510. The adhesive member 540 may be bonded to the recess 1317 and the board 510. The adhesive member 540 may cover the opening 1317s of the recess 1317. The adhesive member 540 may prevent and/or block foreign substances and/or liquid from entering the interior of the electronic device 101 from the outside of the electronic device 101 through the opening 1317s of the recess 1317.

The adhesive member 540 may at least partially surround the opening 1317s of the recess 1317. As an example, the adhesive member 540 may have a hole (not shown) formed in the region facing the opening 1317 so as to surround the opening 1317s of the recess 1317. As another example, the adhesive member 540 may have a hole (not shown) formed in the region facing the opening 1317 and the through-holes 3171 and 3172 so as to surround the opening 1317s of the recess 1317 and the through-holes 3171 and 3172.

Antenna elements may form directional beams. At this time, in order to secure communication performance of antenna elements disposed inside the electronic device, the beam must be formed to pass through a non-conductive part. In other words, the positions of the non-conductive portion, through which the beam passes, and the antenna elements need to be fixed. Accordingly, much research is being conducted on methods for stably fixing the antenna elements inside electronic devices.

The disclosure may be intended to firmly fix the antenna module inside the electronic device.

The disclosure may be intended to increase the adhesion area between the side wall of the electronic device on which the antenna module is disposed and the cover attached to the side wall.

The technical problems to be addressed in the disclosure are not limited to what mentioned above, and may be determined in various ways without departing from the idea and scope of the disclosure.

In the electronic device according to various embodiments of the disclosure, since a non-conductive cap disposed outside the side wall passes through the side wall and then is fastened to the antenna module disposed inside the side wall, it is possible to firmly fix the antenna module inside the electronic device.

In the electronic devices according to various embodiments of the disclosure, since the antenna module is fixed through the lateral surface of the side wall of the electronic device, it is possible to increase the adhesion area attached to a region (e.g., the front or rear surface), excluding the lateral surface of the side wall.

The effects obtainable from the disclosure are not limited to the effects mentioned above, and other effects not mentioned may be clearly understood by those skilled in the art to which the disclosure belongs from the description below.

An electronic device according to an embodiment of the disclosure may include a housing 301 including a side wall 310, wherein the side wall 310 may include a recess 317 recessed from an outer surface 312s of the side wall 310.

The electronic device according to an embodiment of the disclosure may include a non-conductive cap 500, 1500, or 2500 disposed in the recess 317 and including a protruding portion 520, 530, 1520, or 1530 passing through the recess 317.

The electronic device according to an embodiment of the disclosure may include an antenna module 410 disposed opposite to the cap 500, 1500, or 2500 with respect to the recess 317 and including at least one antenna element 411, 412, and 413 disposed to face the recess 317.

The electronic device according to an embodiment of the disclosure may include a bracket 420 or 2420 disposed in the inside S2 of the housing 301 such that the antenna module 410 is mounted thereon, and including a coupling hole 4221, 4231, 2424, or 2425 through which the protruding portion 520, 530, 1520, or 1530 passes.

According to an embodiment of the disclosure, the bracket 420 or 2420 may include a seating portion 424 supporting the antenna module 410.

According to an embodiment of the disclosure, the bracket 420 or 2420 may include a coupling portion 422, 423, 2422, or 2423 extending outward from the seating portion 424 and including the coupling hole 4221, 4231, 2424, or 2425.

According to an embodiment of the disclosure, the coupling portion 422 or 423 may be bent toward the protruding portion 1520 or 1530.

According to an embodiment of the disclosure, the cap 1500 may include a groove 1521 or 1531 formed on a lateral surface of the protruding portion 1520 or 1530 such that an end 4223 of the coupling portion 422 or 423 is inserted thereinto.

According to an embodiment of the disclosure, an end of the protruding portion 1520 or 1530 may include an inclined surface 1522 or 1532 that is inclined downward toward the groove 1521 or 1531 and connected to the edge of the groove 1521 or 1531.

According to an embodiment of the disclosure, the electronic device may further include a guide hole 314 formed on the side wall 310, wherein the guide hole 314 has a shape corresponding to the bracket 420 on which the antenna module 410 is mounted such that the bracket 420 passes through the guide hole 314.

According to an embodiment of the disclosure, the electronic device may further include a flexible printed circuit board (FPCB) 430 that is electrically connected to the antenna module 410 and extends from the antenna module 410 to the inside of the housing 301 through the guide hole 314.

According to an embodiment of the disclosure, the FPCB 430 may include a plate 431 where a connector 431a to be connected to the antenna module 410 is disposed.

According to an embodiment of the disclosure, the coupling portion 422, 423, 2422, or 2423 of the FPCB 430 may overlap the plate 431 of the FPCB 430 in a protruding direction of the protruding portion 520, 530, 1520, or 1530.

According to an embodiment of the disclosure, the guide hole 314 may include a first region 3143 that has a shape corresponding to the coupling portion 422, 423, 2422, or 2423 such that the coupling portion passes therethrough.

According to an embodiment of the disclosure, the guide hole 314 may include a second region 3141 that is connected to the edge of the first region 3143 such that at least a portion of the FPCB 430 passes therethrough and has a width less than the width of the first region 3143.

According to an embodiment of the disclosure, the housing 301 may include a cover 380 that is attached to a rear surface 313 of the side wall 310 in which the guide hole 314 is defined, and covers the guide hole 314.

According to an embodiment of the disclosure, the electronic device may include an adhesive member 318 comprising an adhesive material and disposed between the rear surface 313 of the side wall 310 and the cover 380, and having a loop shape of which one side is open.

According to an embodiment of the disclosure, the coupling hole 2424 or 2425 may be an elongated slot.

According to an embodiment of the disclosure, the central axis of the protruding portion 520 or 530 may be spaced apart from the center of the coupling hole 2424 or 2425.

According to an embodiment of the disclosure, the electronic device may include an adhesive member 540 or 2540 disposed between the cap 500 or 2500 and the recess 317 so as to surround the protruding portion 520 or 530.

According to an embodiment of the disclosure, the cap 2500 may include a stepped portion 2511 that is stepped toward the recess 317 and comes into contact with the recess 317.

According to an embodiment of the disclosure, the electronic device may include a sealer 521 or 531 formed at the perimeter of the protruding portion 520 or 530 so as to seal the gap between the protruding portion 520 or 530 and the recess 317.

According to an embodiment of the disclosure, the antenna module 410 may include a base board 414 supported by the seating portion 424.

According to an embodiment of the disclosure, the antenna module 410 may include the at least one antenna element 411, 412, and 413 disposed on one surface of the base board 414 or inside the same.

According to an embodiment of the disclosure, the electronic device may include a bracket 1420 disposed in the inside S2 of the housing 301 such that the antenna module 410 is mounted thereon, and configured to overlap the end of the protruding portion 520 or 530.

According to an embodiment of the disclosure, the electronic device may include a flange portion 1422 or 1423 extending from the seating portion 1424 so as to surround the protruding portion 520 or 530 and so as to be caught by the protruding portion 520 or 530.

According to an embodiment of the disclosure, the end of the protruding portion 520 or 530 may be located between the guide hole 314 and the flange portion 1422 or 1423 in the entry/exit direction of the bracket 1420.

According to an embodiment of the disclosure, the flange portion 1422 or 1423 may overlap the plate 431 of the FPCB 430 in the protruding direction of the protruding portion 520 or 530.

According to an embodiment of the disclosure, the guide hole 314 may include a first region 3143 having a shape corresponding to the flange portion 1423 such that the flange portion 1423 passes therethrough.

According to an embodiment of the disclosure, the guide hole 314 may include a second region 3141 connected to the edge of the first region 3143 such that at least a portion of the FPCB 430 passes therethrough and having a width less than that of the first region 3143.

Ordinal numbers such as first, second, or the like are used simply for the purpose of distinguishing one element from another element, and do not limit the elements.

The drawings in the disclosure include x, y, and z coordinate axes of the same direction. The coordinate axes included in the drawings are provided for convenience of explanation, and the directions indicated by the respective axes (x-axis, y-axis, and z-axis) do not have directionalities such as the front/back direction, the upward/downward direction, the left/right directions, or the like, and it may be understood that the directions in which the respective axes are directed indicate the +x, +y, and +z directions, respectively, and that the opposite directions thereof indicate the −x, −y, and −z directions, respectively. Hereinafter, embodiment(s) of the disclosure will be described with reference to the x, y, and z coordinate axes.

Although specific embodiments have been described above in the detailed description of the disclosure, it will be understood that the various embodiments are intended to be illustrative, not limiting. It will be further apparent to those skilled in the art that various modifications and changes may be made thereto without departing from the scope of the disclosure. It will also be understood that that any of the embodiment(s) described herein may be used in conjunction with any other embodiment(s) described herein.

What is claimed is:

1. An electronic device, comprising:
a housing including a side wall, wherein the side wall comprises a recess recessed from an outer surface of the side wall;
a non-conductive cap disposed in the recess and facing the recess, wherein the non-conductive cap includes a protruding portion;
an antenna module disposed opposite to the non-conductive cap with respect to the recess, the antenna module comprising at least one antenna element disposed to face the recess; and
a bracket disposed inside the housing and supporting the antenna module, the bracket including a coupling hole through which the protruding portion is inserted.

2. The electronic device of claim 1,
wherein the bracket comprises:
a seating portion supporting the antenna module; and
a coupling portion extending outward from the seating portion and comprising the coupling hole.

3. The electronic device of claim 2, wherein:
the coupling portion is bent toward the protruding portion,
the non-conductive cap comprises a groove formed on a lateral surface of the protruding portion, and
an end of the coupling portion is inserted into the groove.

4. The electronic device of claim 3,
wherein an end of the protruding portion comprises an inclined surface connected to a boundary of the groove and inclined downward toward the groove.

5. The electronic device of claim 2, further comprising a guide hole formed on the side wall having a shape corresponding to the bracket and configured to allow the bracket and the antenna module seated on the bracket to pass through the guide hole.

6. The electronic device of claim 5, further comprising a flexible printed circuit board (FPCB) electrically connected to the antenna module and extending from the antenna module to an inside of the housing through the guide hole.

7. The electronic device of claim 6, wherein:
the FPCB comprises a plate where a connector is disposed, wherein the antenna module is connected to the connector, and
the coupling portion overlaps the plate of the FPCB in a protruding direction of the protruding portion.

8. The electronic device of claim 6, wherein:
the guide hole comprises:
a first region, wherein the coupling portion is configured to pass through the first region; and
a second region connected to the first region, wherein at least a portion of the plate is configured to pass through the second region,
wherein a width of the second region is less than a width of the first region.

9. The electronic device of claim 5, further comprising a cover attached to a rear surface of the side wall, the cover covering the guide hole.

10. The electronic device of claim 9, further comprising an adhesive member comprising an adhesive material and disposed between the rear surface of the side wall and the cover, wherein the adhesive member has a loop shape of which one side is open.

11. The electronic device of claim 1, wherein:
the coupling hole is an elongated slot, and
a central axis of the protruding portion is spaced apart from a center of the coupling hole.

12. The electronic device of claim 1, further comprising an adhesive member comprising an adhesive material disposed between the non-conductive cap and the recess, the adhesive member surrounding the protruding portion.

13. The electronic device of claim 12, wherein:
the non-conductive cap comprises a stepped portion stepped toward the recess and
the stepped portion is configured to contact the recess of the side wall.

14. The electronic device of claim 1, further comprising:
a sealer disposed on a lateral surface of the protruding portion and sealing a gap between the protruding portion and the recess.

15. The electronic device of claim 1,
wherein the antenna module comprises:
a base board supported by the seating portion; and
the at least one antenna element is disposed on one surface of the base board or inside the base board.

16. An electronic device comprising:
a housing comprising a side wall including a recess recessed from an outer surface of the side wall;
a non-conductive cap disposed in the recess and comprising protruding portions passing through a non-conductive portion of the side wall;
an antenna module disposed opposite to the cap with respect to the recess and comprising at least one antenna element disposed to face the recess of the side wall; and
a bracket disposed in the inside of the housing such that the antenna module is mounted thereon, and configured to overlap the ends of the protruding portions.

17. The electronic device of claim 16, wherein the bracket comprises:
a seating portion in which the antenna module is disposed; and
flange portions extending from the seating portion to surround the protruding portions and to be caught by the protruding portions.

18. The electronic device of claim 17, further comprising a guide hole formed on the side wall and having a shape corresponding to the bracket such that the bracket on which the antenna module is mounted enters and exits therethrough,
wherein the ends of the protruding portions are located between the guide hole and the flange portions in the entry/exit direction of the bracket.

19. The electronic device of claim 18, comprising a plate on which a connector connected to the antenna module is disposed, and further comprising a flexible printed circuit board (FPCB) extending to the inside of the housing through the guide hole,
wherein the flange portions overlap the plate of the FPCB in the protruding directions of the protruding portions.

20. The electronic device of claim 19, wherein the guide hole comprises:
a first region having a shape corresponding to the flange portion and configured to allow the flange portion to pass through the first region; and
a second region connected to an edge of the first region and configured to allow at least a portion of the FPCB to pass through the second region, the second region having a width less than a width of the first region.
